(19) United States
(12) Patent Application Publication
(10) Pub. No.: US 2025/0024670 A1
(43) Pub. Date: Jan. 16, 2025

(54) VERTICAL FUSE ARRAY ARCHITECTURE

(71) Applicant: Micron Technology, Inc., Boise, ID (US)

(72) Inventors: Antonino Rigano, CERNUSCO SUL NAVIGLIO (IT); Marcello Calabrese, Monza (MB) (IT); Tommaso Rossi, CERRO AL LAMBRO (IT)

(21) Appl. No.: 18/771,079

(22) Filed: Jul. 12, 2024

Related U.S. Application Data
(60) Provisional application No. 63/526,871, filed on Jul. 14, 2023.

(51) Int. Cl. H10B 20/25; G11C 17/16; G11C 17/18

(52) U.S. Cl. CPC H10B 20/25; G11C 17/16; G11C 17/18

(57) ABSTRACT

Methods, systems, and devices for vertical fuse array architecture are described. A memory system may include a one-time programmable array of antifuses which are manufactured using techniques similar to manufacturing other components, layers, or both of the memory system. Each antifuse of the array may include a semiconductor channel extending vertically from a substrate and coupled with an oxide material. Each antifuse may further be coupled with a word line and a digit line, which may be configured to break down the oxide material to couple the digit line and word line. In some examples, the oxide material may be arranged on one or more sidewalls of the channel. Additionally or alternatively, the oxide material may be arranged on an upper surface of an upper terminal of the channel.

### CROSS REFERENCE

The present Application for Patent claims priority to U.S. Patent Application No. 63/526,871 by Rigano et al., entitled “VERTICAL FUSE ARRAY ARCHITECTURE” filed Jul. 14, 2023, which is assigned to the assignee hereof, and which is expressly incorporated by reference in its entirety herein.

### TECHNICAL FIELD

The following relates to one or more systems for memory, including vertical fuse array architecture.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source. FeRAM may be able to achieve densities similar to volatile memory but may have non-volatile properties due to the use of a ferroelectric capacitor as a storage device.

### BRIEF DESCRIPTION OF THE DRAWINGS

FIG. 1 illustrates an example of a system that supports vertical fuse array architecture in accordance with examples as disclosed herein.

FIG. 2 illustrates an example of a memory die that supports vertical fuse array architecture in accordance with examples as disclosed herein.

FIG. 3 illustrates an example of a top down view of a system that supports vertical fuse array architecture in accordance with examples as disclosed herein.

FIG. 4 illustrates an example of cross-sectional view of a system that supports vertical fuse array architecture in accordance with examples as disclosed herein.

FIGS. 5A and 5B illustrate examples of a three dimensional view of a system that supports vertical fuse array architecture in accordance with examples as disclosed herein.

FIGS. 6A and 6B illustrate examples of a three dimensional view of a system that supports vertical fuse array architecture in accordance with examples as disclosed herein.

FIGS. 7A and 7B illustrate examples of a top down view of a system and a schematic of operation of the system of that supports vertical fuse array architecture in accordance with examples as disclosed herein.

FIGS. 8A, 8B, and 8C illustrates examples of a top down views and a cross sectional view of a system that supports vertical fuse array architecture in accordance with examples as disclosed herein.

### DETAILED DESCRIPTION

Some memory systems may include one or more arrays of one-time programmable (OTP) memory cells, as well as arrays of volatile or non-volatile memory cells. Such arrays of OTP memory cells may store parameters (e.g., configuration parameters, calibration parameters) for operations of the memory system, such as read or write voltage, timing parameters, metadata, or a combination thereof. Additionally or alternatively, an OTP array may store information associated with defective rows, columns, or memory cells of memory arrays of the memory system. Some memory system may additionally include one or more vertical thin-film transistors (TFTs), which may be implemented as switching components for the memory system. A manufacturer of the memory system may use different types of operations to manufacture vertical TFTs and OTP arrays (e.g., material deposition procedures, masking procedures, etching procedures). However, using different types of operations to form vertical TFTs and OTP arrays may increase complexity of manufacturing, for example by increasing the quantity of manufacturing steps, using additional manufacturing machinery, among other examples.

As described herein, a memory system may include an OTP array of antifuses which are manufactured using techniques similar to manufacturing other components, layers, or both of the memory system. Each antifuse of the array may include a semiconductor channel extending vertically from a substrate and coupled with a dielectric material, such as an oxide material. Each antifuse may further be coupled with a word line and a digit line, which may be configured to break down the dielectric material (e.g., “blow” the antifuse) to couple the digit line and word line. In some examples, the dielectric material may be arranged on one or more sidewalls of the channel. Additionally or alternatively, the oxide material may be arranged on an upper surface of an upper terminal of the channel. Because such an antifuse may include components similar to a vertical TFT (e.g., a channel extending vertically), the antifuse may be manufactured using techniques similar to manufacturing a vertical TFT, which may reduce complexity of manufacturing the memory system.

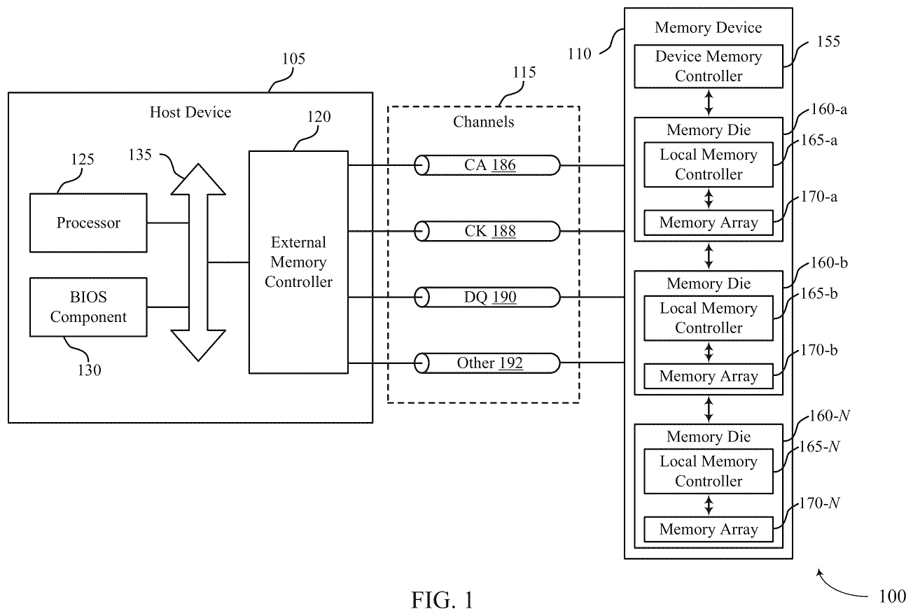

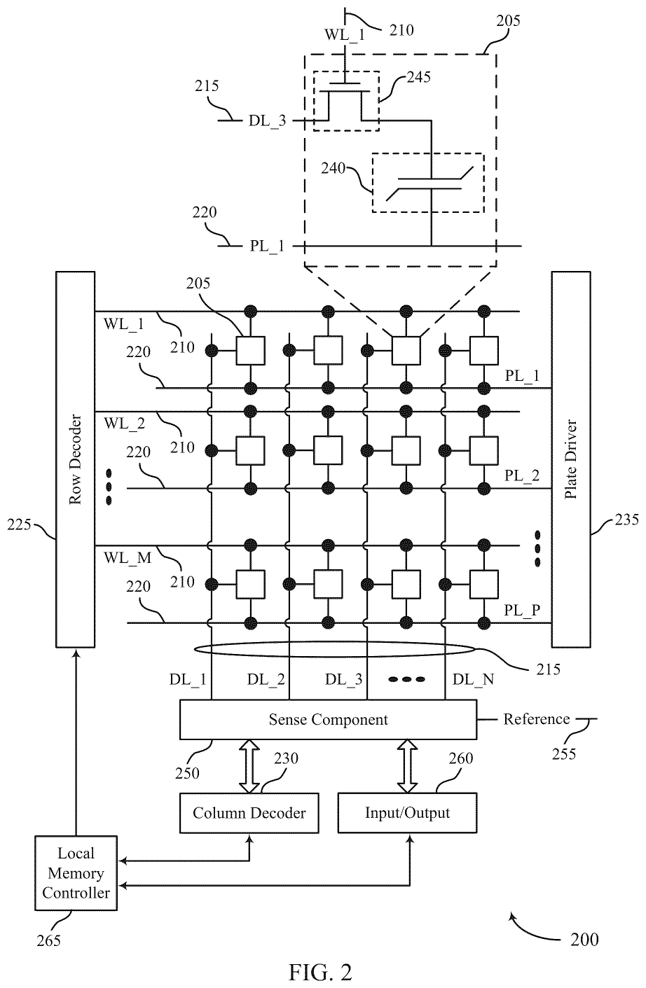

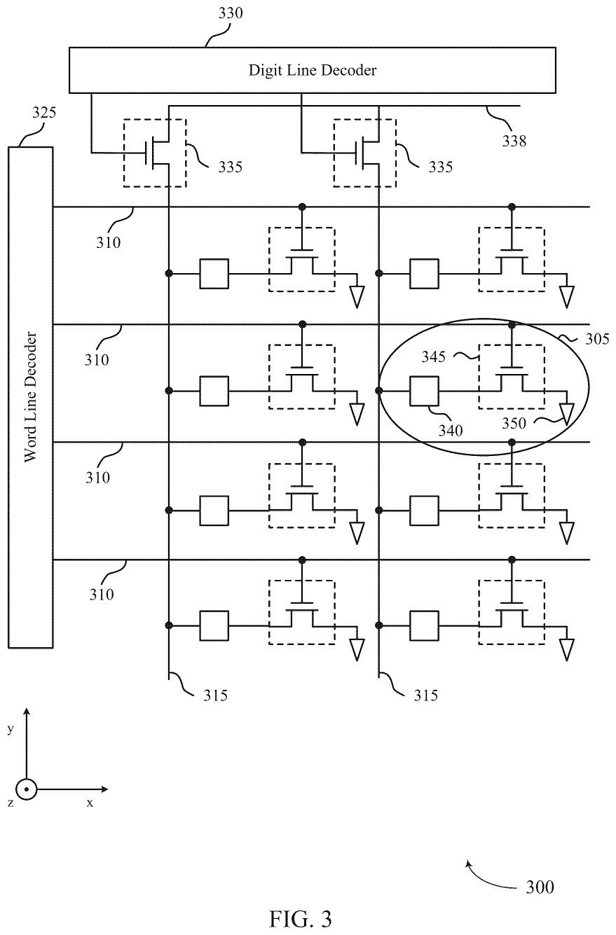

Features of the disclosure are initially described in the context of systems and dies with reference to FIGS. 1 and 2. Features of the disclosure are described in the context of top views, cross sectional views, and three dimensional views of systems with reference to FIGS. 3 through 8C.

FIG. 1 illustrates an example of a system 100 that supports vertical fuse array architecture in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

A memory die 160 may be an example of a two-dimensional (2D) array of memory cells or may be an example of a three-dimensional (3D) array of memory cells. In some examples, a 2D memory die 160 may include a single memory array 170. In some examples, a 3D memory die 160 may include two or more memory arrays 170, which may be stacked on top of one another or positioned next to one another (e.g., relative to a substrate). In some examples, memory arrays 170 in a 3D memory die 160 may be referred to as or otherwise include different sets (e.g., decks, levels, layers, dies). A 3D memory die 160 may include any quantity of stacked memory arrays 170 (e.g., two high, three high, four high, five high, six high, seven high, eight high). In some 3D memory dies 160, different decks may share a common access line such that some decks may share one or more of a word line, a digit line, or a plate line.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

In some cases, a memory device 110 may include an OTP array of antifuses which are manufactured using techniques similar to manufacturing other components, layers, or both of the memory device 110. Each antifuse of the array may include a semiconductor channel extending vertically from a substrate and coupled with an oxide material. Each antifuse may further be coupled with a word line and a digit line, which may be configured to break down the oxide material (e.g., “blow” the antifuse) to couple the digit line with a voltage when the word line is asserted. In some examples, the oxide material may be arranged on one or more sidewalls of the channel. Additionally or alternatively, the oxide material may be arranged on an upper surface of an upper terminal of the channel (e.g., with the TFT serving as a selection device). Because such an antifuse may include components similar to a vertical TFT (e.g., a channel extending vertically), the antifuse may be manufactured using techniques similar to manufacturing a vertical TFT, which may reduce complexity of manufacturing the memory device 110.

FIG. 2 illustrates an example of a memory die 200 that supports vertical fuse array architecture in accordance with examples as disclosed herein. The memory die 200 may be an example of the memory dies 160 described with reference to FIG. 1. In some examples, the memory die 200 may be referred to as a memory chip, a memory device, or an electronic memory apparatus. The memory die 200 may include one or more memory cells 205 that may each be programmable to store different logic states (e.g., programmed to one of a set of two or more possible states). For example, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). In some examples, the memory cells 205 may be arranged in an array, such as a memory array 170 described with reference to FIG. 1.

In some examples, a memory cell 205 may store a state (e.g., a polarization state, a dielectric charge) representative of the programmable states in a capacitor. The memory cell 205 may include a logic storage component, such as capacitor 240, and a switching component 245 (e.g., a cell selection component). A first node of the capacitor 240 may be coupled with the switching component 245 and a second node of the capacitor 240 may be coupled with a plate line 220. The switching component 245 may be an example of a transistor or any other type of switch device that selectively establishes or de-establishes electronic communication between two components. In FeRAM architectures, the memory cell 205 may include a capacitor 240 (e.g., a ferroelectric capacitor) that includes a ferroelectric material to store a charge (e.g., a polarization) representative of the programmable state.

The memory die 200 may include access lines (e.g., word lines 210, digit lines 215, plate lines 220) arranged in a pattern, such as a grid-like pattern. An access line may be a conductive line coupled with a memory cell 205 and may be used to perform access operations on the memory cell 205. In some examples, word lines 210 may be referred to as row lines. In some examples, digit lines 215 may be referred to as column lines or bit lines. References to access lines, row lines, column lines, word lines, digit lines, bit lines, or plate lines, or their analogues, are interchangeable without loss of understanding. Memory cells 205 may be positioned at intersections of the word lines 210, the digit lines 215, or the plate lines 220.

Operations such as reading and writing may be performed on memory cells 205 by activating access lines such as a word line 210, a digit line 215, or a plate line 220. By biasing a word line 210, a digit line 215, and a plate line 220 (e.g., applying a voltage to the word line 210, digit line 215, or plate line 220), a single memory cell 205 may be accessed at their intersection. The intersection of a word line 210 and a digit line 215 in a two-dimensional or in a three-dimensional configuration may be referred to as an address of a memory cell 205. Activating a word line 210, a digit line 215, or a plate line 220 may include applying a voltage to the respective line.

Accessing the memory cells 205 may be controlled through a row decoder 225, a column decoder 230, or a plate driver 235, or any combination thereof. For example, a row decoder 225 may receive a row address from the local memory controller 265 and activate a word line 210 based on the received row address. A column decoder 230 may receive a column address from the local memory controller 265 and activate a digit line 215 based on the received column address. A plate driver 235 may receive a plate address from the local memory controller 265 and activate a plate line 220 based on the received plate address.

Selecting or deselecting the memory cell 205 may be accomplished by activating or deactivating the switching component 245. The capacitor 240 may be in electronic communication with the digit line 215 using the switching component 245. For example, the capacitor 240 may be isolated from digit line 215 when the switching component 245 is deactivated, and the capacitor 240 may be coupled with digit line 215 when the switching component 245 is activated.

A word line 210 may be a conductive line in electronic communication with a memory cell 205 that is used to perform access operations on the memory cell 205. In some architectures, the word line 210 may be in electronic communication with a gate of a switching component 245 of a memory cell 205 and may be operable to control the switching component 245 of the memory cell. In some architectures, the word line 210 may be in electronic communication with a node of the capacitor of the memory cell 205 and the memory cell 205 may not include a switching component.

A digit line 215 may be a conductive line that couples the memory cell 205 with a sense component 250. In some architectures, the memory cell 205 may be selectively coupled with the digit line 215 during portions of an access operation. For example, the word line 210 and the switching component 245 of the memory cell 205 may be operable to selectively couple or isolate the capacitor 240 of the memory cell 205 and the digit line 215. In some architectures, the memory cell 205 may be in electronic communication (e.g., constant) with the digit line 215.

The sense component 250 may determine a state (e.g., a polarization state, a charge) stored on the capacitor 240 of the memory cell 205 and determine a logic state of the memory cell 205 based on the detected state. The sense component 250 may include one or more sense amplifiers to amplify the signal output of the memory cell 205. The sense component 250 may compare the signal received from the memory cell 205 across the digit line 215 to a reference 255 (e.g., a reference voltage, a reference line). The detected logic state of the memory cell 205 may be provided as an output of the sense component 250 (e.g., to an input/output 260), and may indicate the detected logic state to another component of a memory device (e.g., a memory device 110) that includes the memory die 200.

The local memory controller 265 may control the operation of memory cells 205 through the various components (e.g., row decoder 225, column decoder 230, plate driver 235, and sense component 250). The local memory controller 265 may be an example of the local memory controller 165 described with reference to FIG. 1. In some examples, one or more of the row decoder 225, column decoder 230, and plate driver 235, and sense component 250 may be co-located with the local memory controller 265. The local memory controller 265 may be operable to receive one or more of commands or data from one or more different memory controllers (e.g., an external memory controller 120 associated with a host device 105, another controller associated with the memory die 200), translate the commands or the data (or both) into information that can be used by the memory die 200, perform one or more operations on the memory die 200, and communicate data from the memory die 200 to a host (e.g., a host device 105) based on performing the one or more operations. The local memory controller 265 may generate row signals and column address signals to activate the target word line 210, the target digit line 215, and the target plate line 220. The local memory controller 265 also may generate and control various signals (e.g., voltages, currents) used during the operation of the memory die 200. In general, the amplitude, the shape, or the duration of an applied voltage or current discussed herein may be varied and may be different for the various operations discussed in operating the memory die 200.

The local memory controller 265 may be operable to perform one or more access operations on one or more memory cells 205 of the memory die 200. Examples of access operations may include a write operation, a read operation, a refresh operation, a precharge operation, or an activate operation, among others. In some examples, access operations may be performed by or otherwise coordinated by the local memory controller 265 in response to various access commands (e.g., from a host device 105). The local memory controller 265 may be operable to perform other access operations not listed here or other operations related to the operating of the memory die 200 that are not directly related to accessing the memory cells 205.

In some cases, a memory die 200 may include or may be coupled with an OTP array of antifuses which are manufactured using techniques similar to manufacturing other components, layers, or both of the memory die 200. Each antifuse of the array may include a semiconductor channel extending vertically from a substrate and coupled with an oxide material. Each antifuse may further be coupled with a word line 210 and a digit line 215, which may be configured to break down the oxide material (e.g., “blow” the antifuse) to couple the digit line 215 and word line 210 (e.g., by applying a voltage potential above a threshold across the word line 210 and digit line 215). In some examples, the oxide material may be arranged on one or more sidewalls of the channel. Additionally or alternatively, the oxide material may be arranged on an upper surface of an upper terminal of the channel (e.g., with the TFT serving as a selection device). Because such an antifuse may include components similar to a vertical TFT (e.g., a channel extending vertically), the antifuse may be manufactured using techniques similar to manufacturing a vertical TFT, which may reduce complexity of manufacturing the memory die 200.

FIG. 3 illustrates an example of a schematic of a system 300 that supports vertical fuse array architecture in accordance with examples as disclosed herein. The system 300 may be an antifuse memory array. The system 300 may include one or more antifuse cells 305 that may each be programmed to store different logic states (e.g., set to a logic 1 or a logic 0). In some examples, the antifuse cells 305 may be arranged in an array of rows and columns. The system 300 may be implemented in, and thus coupled with, a memory device (e.g., a memory device 110). For example, the system 300 may be an example of an OTP fuse array for a memory device, an example of a supporting array for a memory die 200, or both. The system 300 may support operations of a memory device. For example, the system 300 may store parameters (e.g., configuration parameters, calibration parameters) for operations of the memory device, such as read or write voltage, timing parameters, metadata, or a combination thereof. Additionally or alternatively, the system 300 may store information associated with defective rows, columns, or memory cells of memory arrays of the memory system.

In some examples, an antifuse cell 305 may store a state representative of the programmable states in an antifuse 340. The antifuse cell 305 may include a logic storage component, such the antifuse 340. In some examples, an antifuse cell 305 may additionally include a switching component 345, which may selectively couple the antifuse 340 with a voltage source, such as a ground voltage source 350. A first terminal of the antifuse 340 may be selectively coupled with the ground voltage source 350 via the switching component 345 and a second terminal of the antifuse 340 may be coupled with a digit line 315. The switching component 345 may be an example of a transistor or any other type of switch device that selectively establishes or de-establishes electronic communication between two components.

An antifuse cell 305 may be an OTP memory cell. For example, the antifuse 340 of an antifuse cell 305 may initially be in a high-resistance state, which may correspond to the antifuse cell 305 storing a first logic state (e.g., a logic 0). If a sufficiently high voltage (e.g., a voltage greater than a threshold voltage of the antifuse 340) is applied across the antifuse 340, the antifuse 340 may “blow”, and transition to a low-resistance state, which may correspond to a second logic state (a logic 1). In some cases, the process of blowing an antifuse 340 may be referred to as a fuse operation. Because a fuse operation of an antifuse cell 305 may not be reversible, an antifuse cell 305 may be programmed once.

The system 300 may include access lines, such as word lines 310 extending in a first horizontal direction (e.g., the x-direction) and digit lines 315 extending in a second horizontal direction (e.g., the y-direction), and arranged in a grid-like pattern. An access line may be a conductive line coupled with an antifuse cell 305 and may be used to perform access operations (e.g., fuse operations, read operations) on the antifuse cell 305. Operations such as reading and fusing may be performed on antifuse cells 305 by activating access lines such as a word line 310, a digit line 315, or both. By biasing a word line 310 and a digit line 315 (e.g., applying a voltage to the word line 310 or digit line 315), a single antifuse cell 305 may be accessed at their intersection. The intersection of a word line 310 and a digit line 315 may be referred to as an address of an antifuse cell 305. Activating a word line 310 or a digit line 315 may include applying a voltage to the respective line. For example, if the switching component 345 is an n-type transistor, activating the word line 310 may include applying a voltage higher than the threshold voltage of the n-type transistor to activate the n-type transistor (e.g., to electrically couple the source and drain terminals of the n-type transistor). Alternatively, if the switching component 345 is a p-type transistor, activating the word line 310 may include applying a voltage lower than the threshold voltage of the p-type transistor (e.g., a voltage lower than the voltage of the source and drain terminals of the p-type transistors) to activate the p-type transistor.

Accessing the antifuse cells 305 may be controlled through a word line decoder 325, a digit line decoder 330, or both. For example, a word line decoder 325 may receive a row address from a controller (e.g., a memory controller, such as a local memory controller 265) and activate a word line 310 based on the received row address. A digit line decoder 330 may receive a column address from the controller and activate a digit line 315 based on the received column address. In some examples, a digit line decoder 330 may activate a digit line 315 by activating a switching component 335 (e.g., a transistor) associated with the digit line 315. Activating the switching component 335 may apply a voltage to the digit line 315 by coupling the digit line 315 with a voltage source 338.

Fusing the antifuse cell 305 may be accomplished by activating the switching component 345 using a word line 310, which may couple the first terminal of the antifuse 340 with the ground voltage source 350, and applying a first voltage (e.g., a high voltage, a fuse voltage) to a digit line 315 coupled with the second terminal of the antifuse 340. The resulting voltage across the antifuse 340 may be sufficiently high (e.g., may be greater than a gate oxide breakdown voltage of the antifuse 340) to blow the antifuse 340, and thus transition the antifuse 340 from a high resistance state to a low resistance state.

Reading the antifuse cell 305 may be accomplished by activating the switching component 345 and applying a second voltage (e.g., a low voltage, a read voltage less than the gate oxide breakdown voltage of the antifuse 340) to a digit line 315. If the antifuse 340 has been fused (e.g., blown), activating the switching component 345 may couple the digit line 315 with the ground voltage source 350 via the switching component 345. Alternatively, if the antifuse 340 has not been fused, the digit line 315 may remain isolated from the ground voltage source 350. A component coupled with the digit line 315 (e.g., a sense component) may sense the current or voltage on the digit line 315 to determine whether the antifuse 340 has been fused, and thus determine the logic state stored by the antifuse cell 305.

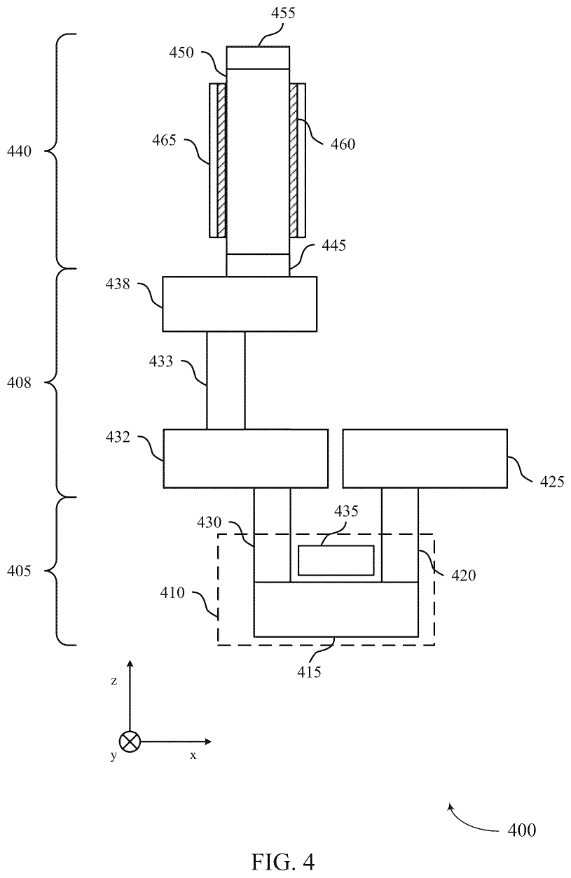

FIG. 4 illustrates an example of cross-sectional view of a system 400 that supports vertical fuse array architecture in accordance with examples as disclosed herein. The system 400 may be an example of a portion of an antifuse cell (e.g., an antifuse cell 305 as described with reference to FIG. 3). The system 400 may be implemented in a memory device (e.g., a memory device 110) manufactured in multiple layers using respective manufacturing operations. For example, the memory device may include a substrate layer which may include a set of transistors or other circuitry (e.g., a complimentary metal-oxide-semiconductor (CMOS) layer), and one or more metal layers which may be used as access lines (e.g., digit lines, word lines, plate lines) for memory cells, such as FeRAM memory cells. The memory device may also include a layer of vertical TFTs between the memory cells and the substrate, which may be used to access the memory cells. For example, each memory cell may include a ferroelectric capacitor having a first node coupled with a first terminal of a TFT, and a second node coupled with a plate line. The TFT may include a second terminal coupled with the substrate, and accordingly the TFT may be activated to couple the memory cell with circuitry in the substrate, for example as part of an access operation.

The system 400 may be manufactured using techniques similar to manufacturing a memory device. For example, the system 400 may include a layer 405 (e.g., a CMOS layer, a CuA layer, a substrate layer) which implements a switching component 410. The switching component 410 may include a channel region 415, a terminal 420 couple with a ground voltage source 425 (e.g., which may be coupled with a conductive trace), and a terminal 430. The switching component 410 may include a gate 435, which may be configured to activate switching component 410 to couple the terminal 420 with the terminal 430. In some cases, the gate 435 may couple with an access line extending in a horizontal direction (e.g., the x-direction), such as a word line 310 as described with reference to FIG. 3.

The system 400 may include a layer 408 formed above the layer 405. The layer 408 may include one or more conductive contacts manufactured using techniques similar to manufacturing metal lines (e.g., access lines, digit lines 215) of a memory device. The layer 408 may include a conductive contact 432 above and coupled with the terminal 430, a conductive pillar 433 above and coupled with the conductive contact 432, and a conductive patch 438 above and coupled with the conductive pillar 433.

The system 400 may include a second layer 440, which may include an example of an antifuse, such as the antifuse 340 as described with reference to FIG. 3. The second layer 440 may be manufactured using techniques similar to forming a TFT layer of a memory device. For example, a step in a manufacturing process of the memory device may deposit or grow portions of the second layer 440 including a semiconductor material used for a channel 450 of the antifuse above the first layer 405 (e.g., and the layer 408), and may, as part of the same step, deposit or grow portions of a TFT layer (e.g., portions which include the semiconductor material) of the memory device. The antifuse may include a terminal 445 coupled with the terminal 430 of switching component 410 via the conductive patch 438, a channel 450 of the semiconductor material extending in a vertical direction (e.g., the z-direction) above the terminal 430, and a terminal 455 above the channel 450. In some examples, the semiconductor material forming the channel 450 may be formed with additional or different doping (e.g., N-type doping) than channels of a TFT layer of a memory device.

The antifuse may include an oxide material 460 disposed on sidewalls of the channel 450, and the second layer 440 may include an access line 465 adjacent to the oxide material 460 and extending in a second horizontal direction (e.g., the y-direction). The access line 465 may be adjacent to the oxide material 460 on multiple sidewalls of the channel 450, as depicted in FIG. 4, or may be adjacent to the oxide material 460 on a single sidewall of the channel 450. In some cases, the access line 465 may be an example of digit line 315 as described with reference to FIG. 3.

A controller may access the antifuse using the access line coupled with the gate 435 and the access line 465. For example, to fuse the antifuse, the controller may activate the switching component 410 to couple the terminal 445 with the ground voltage source 425, and may apply a first voltage to the access line 465. The first voltage may be sufficiently high to cause the oxide material 460 to break down, which may couple (e.g., fuse) the access line 465 with the channel 450. For example, the first voltage may exceed the threshold voltage of the antifuse. Alternatively, to read the antifuse, the controller may activate the switching component 410 and apply a second voltage (e.g., a read voltage) to the access line 465. If the oxide material 460 has been broken down, activating the switching component 410 may couple the access line 465 with the ground voltage source 425. Alternatively, if the oxide material 460 has not been broken down, the access line 465 may remain isolated from the ground voltage source 425. A component coupled with the access line 465 (e.g., a sense component) may sense the current or voltage on the access line 465 to read the logical state stored by the antifuse.

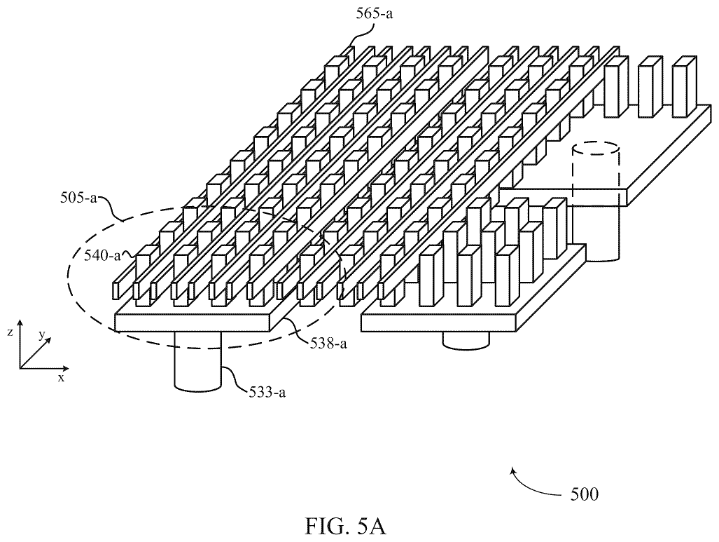

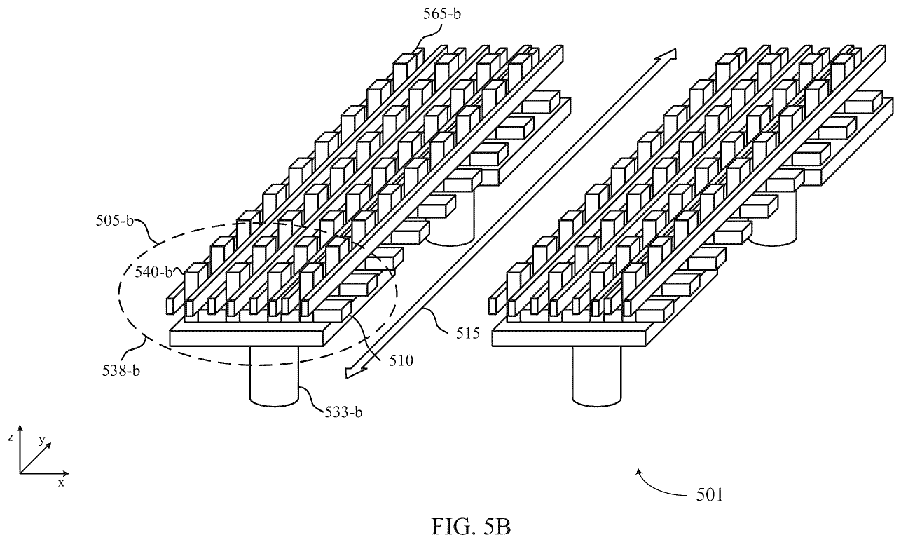

FIGS. 5A and 5B illustrate examples of a three dimensional view of a system 500 and a system 501, respectively, that support vertical fuse array architecture in accordance with examples as disclosed herein. The system 500 and the system 501 may each be an example of an array of antifuse cells 505 (e.g., an array of antifuse cells 505-a, an array of antifuse cells 505-b), which may each be example of an array of antifuse cells 305 as described with reference to FIG. 3. The system 500 and the system 501 may each include a set of antifuses channels 540 (e.g., antifuse channels 540-a, antifuse channels 540-b), which may each include aspects of the second layer 440 as described with reference to FIG. 4, such as the channel 450, the terminal 445, the terminal 455, or a combination thereof, arranged in rows extending along the x-direction and columns extending along the y-direction. Each column of antifuse channels 540 may be adjacent to a respective access line 565 (e.g., an access line 565-a, an access line 565-b), which may be an example of an access line 465. Additionally, each antifuse channel 540 may include an oxide material (e.g., an oxide material 460) formed on one or more sidewalls of the antifuse channel 540 and in contact with the access line 565. For example, an access line 565 may be in contact with the oxide material on one or more sidewalls of the antifuse channel 540.

Each antifuse cell 505 may include a conductive patch 538 (e.g., a conductive patch 538-a, a conductive patch 538-b), which may be an example of a conductive patch 438. The conductive patch 538 may be coupled with a switching component (e.g., a switching component 410), via a conductive pillar 533 (e.g., conductive pillar 533-a, conductive pillar 533-b), which may selectively couple the conductive patch 538 with a ground voltage source. In some examples, multiple antifuse channels 540 may be arranged on a single conductive patch 538 in one or more rows, one or more columns or both. For example, a first column of antifuse channels 540 on the conductive patch 538 may each be coupled with a first access line 565, and a second column of antifuse channels 540 on the conductive patch 538 may each be coupled with a second access line 565. Accordingly, each antifuse cell 505 may be associated with one or more access lines 565 and include one or more antifuse channels 540 having respective terminals coupled with a single conductive patch 538.

The system 500 may include antifuse channels 540 between adjacent antifuse cells 505. For example, the system 500 may include one or more antifuse channels 540 between a first conductive patch 538 and a second conductive patch 538. The one or more antifuse channels 540 may be isolated from the first conductive patch 538 and the second conductive patch 538, and accordingly may not be included in an antifuse cell 505.

Including multiple antifuse channels 540 in a single antifuse cell 505 may improve reliability of breaking down the oxide material during a fuse operation of the antifuse cell 505. For example, as part of the fuse operation, a fuse voltage may be applied across each of the antifuse channels 540 of the antifuse cell 505 (e.g., using the one or more access lines 565 associated with the antifuse cell 505). Because the voltage at which the oxide material for each antifuse channel 540 breaks down may vary (e.g., due to minor differences in coverage area, oxide composition, differences in applied voltage, or a combination thereof), each antifuse channel 540 may have a probability of not successfully fusing during the fusc operation. Accordingly, by including multiple antifuse channels 540 in the antifuse cell 505, the probability of successfully fusing at least one antifuse channel 540 of the antifuse cell 505 may increase. Because having at least one fused antifuse channel 540 on a conductive patch 538 may provide a sufficiently conductive path between an access line 565 and the conductive patch 538, including multiple antifuses channels 540 may thus increase the reliability of a fuse operation for the antifuse cell 505.

Additionally, the system 500 and the system 501 may be manufactured using some processing steps in common with forming a TFT layer of a memory device. For example, a first step in a manufacturing process of the memory device may form the conductive patches 538 by depositing and etching a conductive material, and may, as part of the first step, form portions of one or more digit lines for a memory array of the memory device by depositing and etching the conductive material. Further, a second step in a manufacturing process of the memory device may form the antifuse channel 540 by depositing and etching a semiconductor material, and may, as part of the second step, form portions of a TFT array for a memory array of the memory device by depositing and etching the semiconductor material.

In some examples, the system 501 may be manufactured using additional or modified processing steps of the processing steps used to manufacture the system 501. For example, as part of the processing steps to form the antifuse channels 540-b, a processing step for the system 501 may include an etch of the semiconductor material in the x-direction which may expose the conductive material of the conductive patch 538 (e.g., a ‘full’ trench may be etched in the x-direction). The processing step may also include a ‘partial’ etch of the semiconductor material in the y-direction. For example, the partial etch in the y-direction may not remove a portion of the semiconductor material, which may form one or more second channels 510 extending in the x-direction.

The second channels 510 may couple multiple channels 565-b together within a same antifuse cell 505-b, which may increase conductivity between the multiple channels 565-b. Such increased conductivity may increase the probability of breaking down the oxide material during a fuse operation of an antifuse cell 505-b, and accordingly increase the reliability of a fuse operation. In some cases, the second channels 510 between adjacent antifuse cells 505-b in the x-direction may be separated, for example by etching a trench 515 in the semiconductor material.

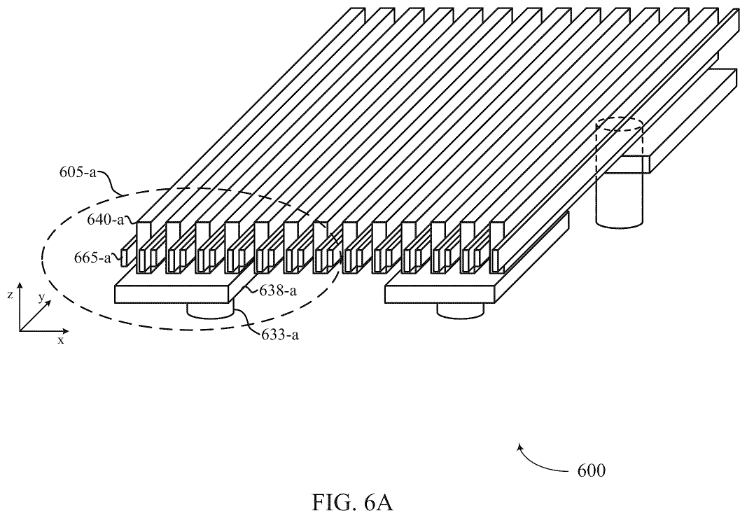

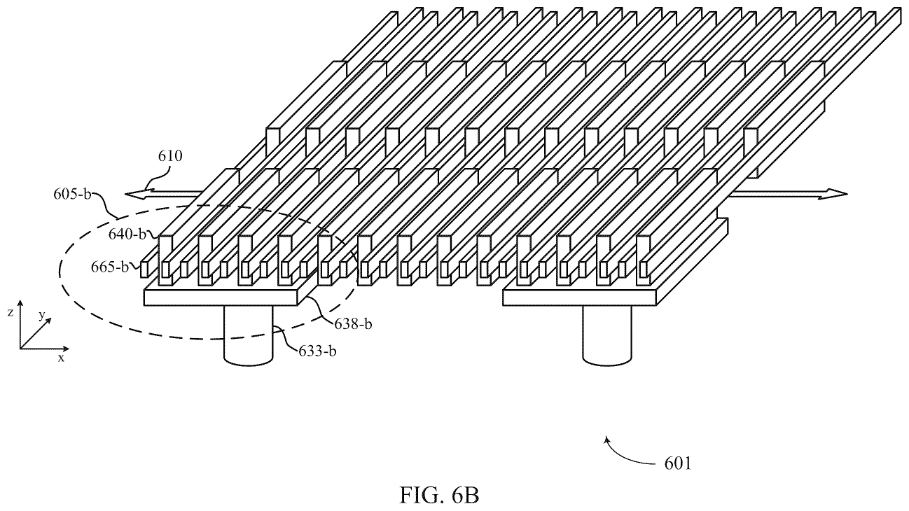

FIGS. 6A and 6B illustrate examples of a three dimensional view of a system 600 and a system 601, respectively, that support vertical fuse array architecture in accordance with examples as disclosed herein. The system 600 and the system 601 may each include aspects of the system 500 and the system 501. For example, the system 600 and the system 601 may include a set of antifuse cells 605 (e.g., a set of antifuse cells 605-a, a set of antifuse cells 605-b), each antifuse cell 605 having a conductive patch 638 (e.g., a conductive patch 638-a, a conductive patch 638-b) coupled with a switching component via a conductive pillar 633 (e.g., a conductive pillar 633-a, a conductive pillar 633-b), and one or more portions of antifuse channels 640 (e.g., antifuse channels 640-a, antifuse channels 640-b) arranged on the conductive patch 638 and coupled with one or more access lines 665 (e.g., access line 665-a, access lines 665-b), which be examples of the corresponding components as described with reference to FIGS. 5A and 5B.

The antifuse channels 640-a of the system 600 may extend across multiple antifuse cells 605-a, multiple conductive patches 638-a, or both. For example, the semiconductor material of a channel of each antifuse channel 640-a, as well as the oxide material between the semiconductor material and an associated access line 665-a, may extend in the y-direction across multiple conductive patches 638-a. Such an extension may increase the surface area of interface between the access lines 665-a and the oxide material, which may increase the probability of breaking down the oxide material during a fuse operation of an antifuse cell 605-a, and accordingly increase the reliability of the fuse operation.

Additionally or alternatively, the antifuse channels 640-b of the system 601 may extend across a single antifuse cells 605-b and a single conductive patches 638-b. For example, as part of manufacturing the antifuse channels 640-b, a trench 610 extending in the x-direction may be etched in the semiconductor material to separate a first antifuse channel 640-b of a first antifuse cell 605-b from a second antifuse channel 640-b of a second antifuse cell 605-b adjacent to the first antifuse cell 605-b in the y-direction. Such a separation may decrease conductivity between adjacent antifuse cells 605-b, which may reduce interference from adjacent antifuse cell 605-b as part of access operations.

Extending the semiconductor material and oxide material of an antifuse channel 640 may be implemented using techniques similar to manufacturing the system 500. However, manufacturing of the system 600 may omit one or more manufacturing steps of manufacturing the system 500. For example, manufacturing the system 500 may include forming linear structure of the semiconductor material, for example by etching one or more trenches in the y-direction of a planar layer of the semiconductor material, and depositing the oxide material on sidewalls of the linear structures. The individual antifuse channels 640 may then be formed by etching one or more trenches in the x-direction. To form the extended channels of the antifuse channels 640, manufacturing the system 600 may omit performing etching the trenches in the x-direction. Such an omission may reduce the complexity of the manufacturing process, for example by reducing the quantity of steps used to manufacture the system 600.

Additionally or alternatively, the antifuse channels 640-b of the system 601 may extend across a single antifuse cells 605-b and a single conductive patches 638-b. For example, as part of manufacturing the antifuse channels 640-b, a trench 610 extending in the x-direction may be etched in the semiconductor material to separate a first antifuse channel 640-b of a first antifuse cell 605-b from a second antifuse channel 640-b of a second antifuse cell 605-b adjacent to the first antifuse cell 605-b in the y-direction. Such a separation may decrease conductivity between adjacent antifuse cells 605-b, which may reduce interference from adjacent antifuse cell 605-b as part of access operations.

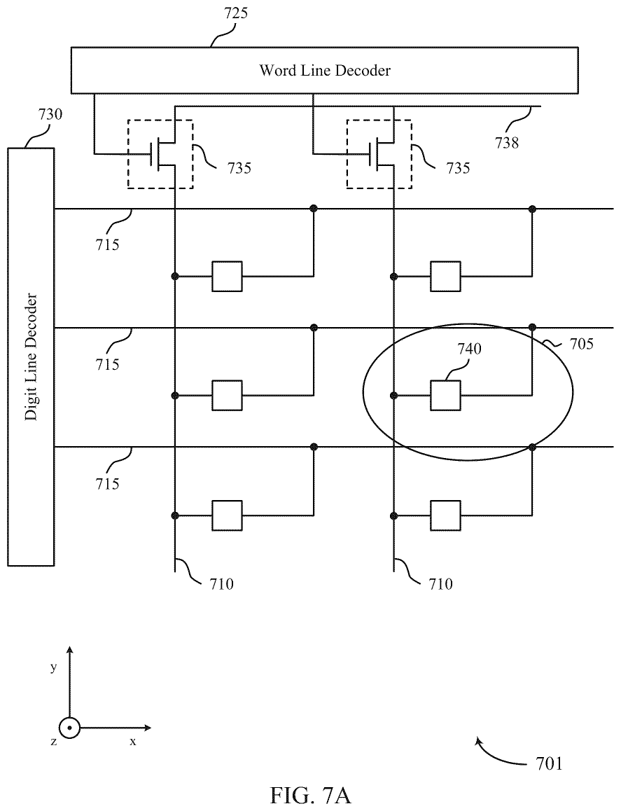

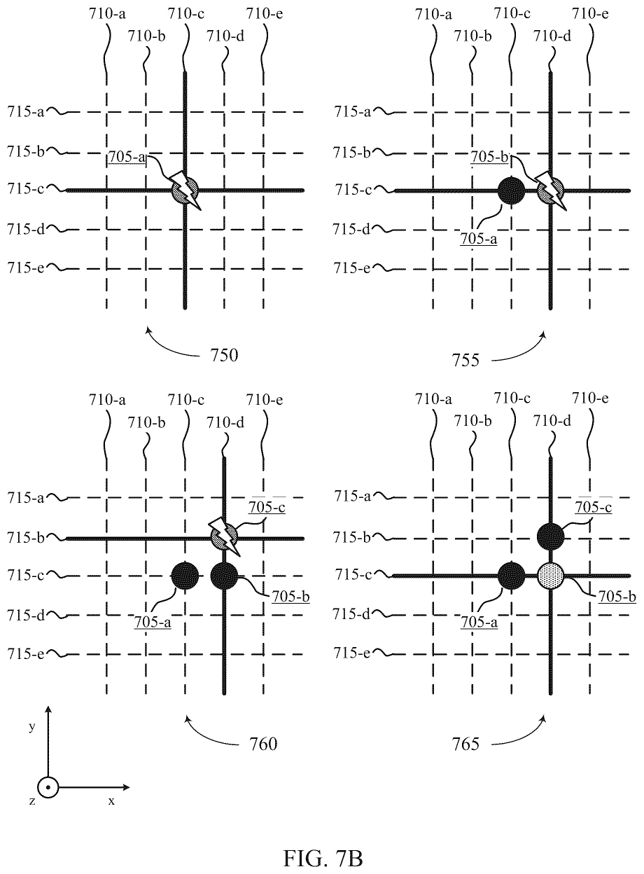

FIGS. 7A and 7B illustrate examples of a top down view of a system 701 and a schematic of operations of the system 701 of that supports vertical fuse array architecture in accordance with examples as disclosed herein. The system 701 may include aspects of the system 300 as described with reference to FIG. 3. For example, the system 701 may be a schematic of an architecture for an antifuse memory array which includes one or more digit lines 715 extending in the x-direction and coupled with a digit line decoder 730 and one or more word lines 710 extending in the y-direction and selectively coupled with a voltage source 738 via respective switching components 735 operated by a word line decoder 725, which may each be an example of the corresponding component as described with reference to FIG. 3.

The system 701 may include an array of antifuse cells 705. An antifuse cell 705 may include some aspects of an antifuse cell 305, 505, 605 or a combination thereof. For example, an antifuse cell 705 may include an antifuse 740, which may include aspects of an antifuse 340, and antifuse channel 540 or 640, or a combination thereof. However, the antifuse cell 705 may not include a switching component to selectively couple the antifuse 740 to an access line. Instead, a terminal of the antifuse 740 (e.g., a terminal 445) may be directly coupled with a digit line 715, and an oxide material formed on one or more sidewalls of a channel of the antifuse 740 (e.g., a channel 450) may be adjacent to a word line 710. Omitting the switching component in an antifuse cell 705 may reduce the footprint of the system 701, which may allow for increased memory density.

To operate the system 701 (e.g., to perform fuse operations, read operations, or both), the word line decoder 725 and the digit line decoder 730 may manage voltages applied to selected word lines 710 and selected digit lines 715, and may place unselected word lines 710 and unselected digit lines 715 in a floating state. For example, FIG. 7B illustrates a sequence of fuse operations, including a fuse operation 750 for an antifuse cell 705-a, a fuse operation 755 for an antifuse cell 705-b, a fuse operation 760 for an antifuse cell 705-c, and a read operation 765 for the antifuse cell 705-b.

To perform the fuse operation 750 for the antifuse cell 705-a, the word line decoder 725 may select the word line 710-c by applying a first voltage to the word line 710-c, and the digit line decoder 730 may select the digit line 715-c by applying a second voltage to the digit line 715-c. The word line decoder 725 may place the unselected word lines 710 (e.g., the word line 710-a, the word line 710-b, the word line 710-d, and the word line 710-c) in a floating state, and the digit line decoder 730 may place the unselected digit lines 715 (e.g., the digit line 715-a, the digit line 715-b, the digit line 715-d, and the digit line 715-c) in a floating state. In some examples, the voltage difference between the first voltage and the second voltage may correspond to the gate oxide breakdown voltage of the antifuse cell 705-a. For example, the first voltage may be a first polarity (e.g., positive 3.5 volts (V)), and the second voltage may be a second polarity with a same magnitude as the first voltage (e.g., negative 3.5 V). Accordingly, applying the first voltage to the word line 710-c and the second voltage to the digit line 715-c may apply a fuse voltage (e.g., 7 V) across the antifuse cell 705-a, which may cause the oxide material of the antifuse cell 705-a to break down, and thus fuse the antifuse cell 705-a.

To perform the fuse operation 755 for the antifuse cell 705-b, the word line decoder 725 may apply the first voltage to the word line 710-d, and the digit line decoder 730 may apply the second voltage to the digit line 715-c. Because the word line decoder 725 may place the word line 710-c in a floating state (e.g., because the word line 710-c may be unselected), current may not flow through the word line 710-c to the digit line 715-c, despite the word line 710-c and digit line 715-c being coupled via the fused antifuse cell 705-a.

Similarly, to perform the fuse operation 760, the word line decoder 725 may apply the first voltage to the word line 710-d, and the digit line decoder 730 may apply the second voltage to the digit line 715-b. Because the digit line decoder 730 may place the digit line 715-c in a floating state (e.g., because the digit line 715-c may be unselected), current may not flow through the digit line 715-c to the word line 710-d, despite the digit line 715-c and word line 710-d being coupled via the fused antifuse cell 705-b.

To perform a read operation for the antifuse cell 705-b, the word line decoder 725 may apply a third voltage (e.g., a read voltage) to the word line 710-d, and the digit line decoder 730 may apply a fourth voltage to the digit line 715-c. In some examples, the fourth voltage may have a different (e.g., lower) magnitude than the first voltage, the second voltage, and the third voltage. For example, the fourth voltage may be a zero voltage. Accordingly, the voltage across the antifuse cell 705-b may be less than the gate oxide breakdown voltage of the antifuse cell 705-b. Thus, if the antifuse cell 705-b has been fused (e.g., as in operation 755), a current may flow between the word line 710-d and the digit line 715-c, which may correspond to reading a first logic state (e.g., a logic 1). Alternatively, if the antifuse cell 705-b has not been fused, the word line 710-d and the digit line 715-c may remain isolated, and a current may not flow between the word line 710-d and the digit line 715-c, which may correspond to reading a second logic state (e.g., a logic 0). Because the digit line decoder 730 may place the digit line 715-b in a floating state and the word line decoder 725 may place the word line 710-c in a floating state (e.g., because the digit line 715-b and the word line 710-c may be unselected), current may not flow between the unselected access lines and the selected access lines, despite the digit line 715-b and word line 710-d being coupled via the fused antifuse cell 705-c, and the digit line 715-c and word line 710-c being coupled via the fused antifuse cell 705-a.

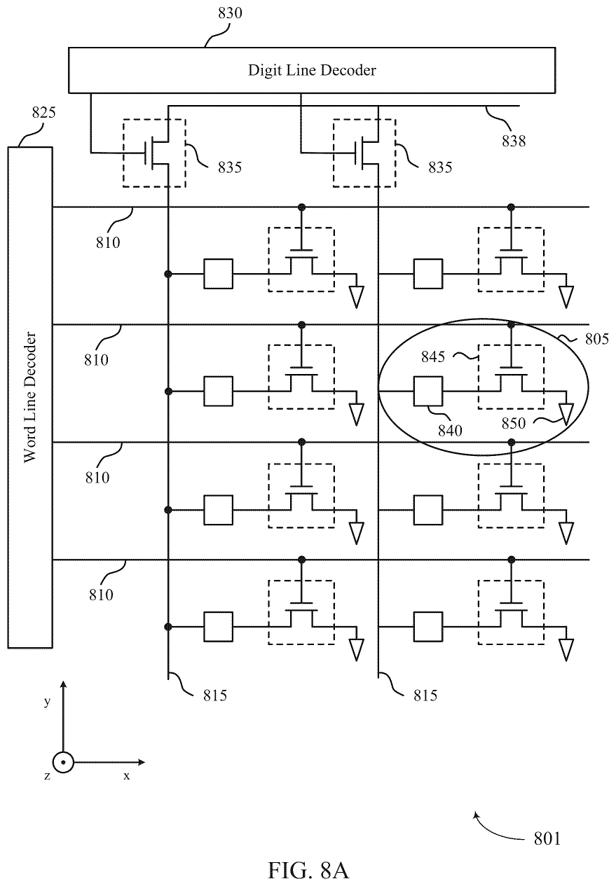

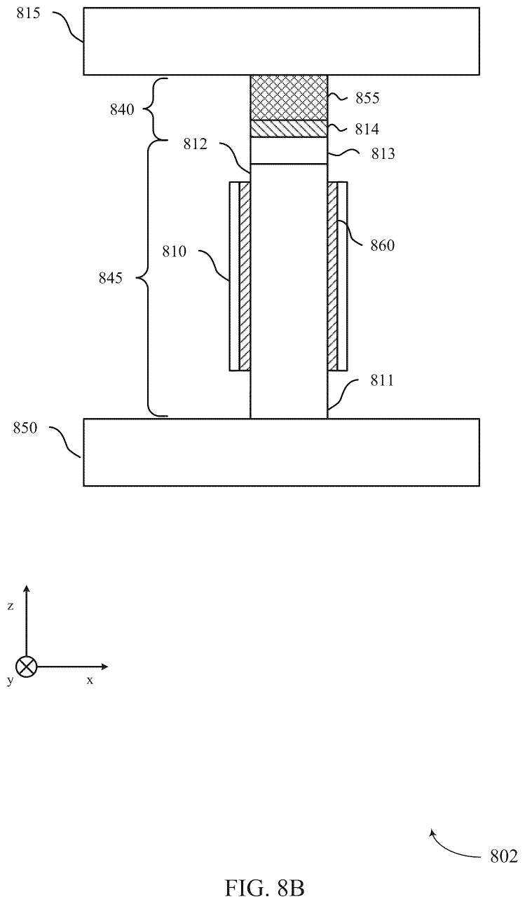

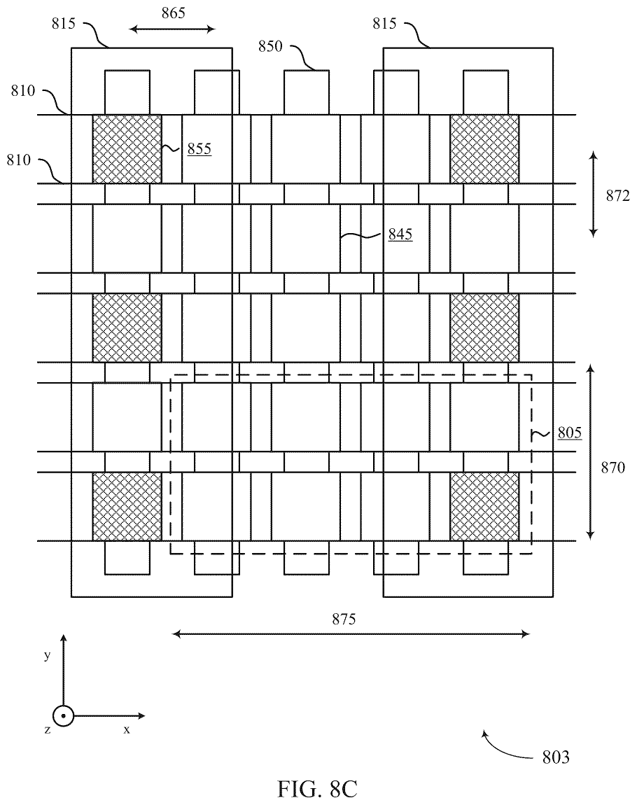

FIGS. 8A, 8B, and 8C illustrates examples of top down views of systems 801 and 803, and a cross sectional view of a system 802 that supports vertical fuse array architecture in accordance with examples as disclosed herein. The system 801 may include aspects of the system 300 as described with reference to FIG. 3. For example, the system 801 may be a schematic of an architecture for an antifuse memory array which includes one or more digit lines 815 extending in the y-direction and selectively coupled with a voltage source 838 via respective switching components 835 operated by a digit line decoder 830, and one or more word lines 810 extending in the x-direction and coupled with a word line decoder 825, which may each be an example of the corresponding component as described with reference to FIG. 3.

The system 801 may include an array of antifuse cells 805. An antifuse cell 805 may include an antifuse 840 coupled between a switching component 845 and a digit line 815. The switching component 845 may selectively couple the antifuse 840 with a ground voltage source 850, and may be activated by activating an associated word line 810.

The switching component 845 may be an example of a vertical TFT. For example, FIG. 8B illustrates a cross sectional view of a vertical TFT. The switching component 845 may include a terminal 811 coupled with a ground voltage source (e.g., coupled to trace 850) below the terminal 811, a channel 812 extending vertically (e.g., in the z-direction) above the terminal 811, and a terminal 813 above the channel 812. The switching component 845 may be operated using a word line 810 (e.g., the word line 810 may act as the gate of the vertical TFT). Accordingly, activating the word line 810 may cause the switching component 845 to become conductive, and thus couple the terminal 811 with the terminal 813. In some examples, the switching component 845 may include an oxide material 860, which may be an example of the oxide material 460 as described with reference to FIG. 4, between the word line 810 and the channel 812.

The terminal 813 of the switching component 845 may be coupled with the antifuse 840 positioned above the terminal 813. The antifuse 840 may include a conductive contact 855 above the terminal 813, and an oxide material 814 between the terminal 813 and the conductive contact 855. The conductive contact 855 may further be coupled with a digit line 815 positioned above the conductive contact.

In some examples, the antifuse cell 805 may be implemented using a single switching component 845 (e.g., a single vertical TFT) coupled with a corresponding antifuse 840, as described with reference to FIG. 8B. Additionally or alternatively, the antifuse cell 805 may be implemented using multiple switching components 845 (e.g., multiple vertical TFTs), each switching component 845 coupled with a respective antifuse 840. In such examples, the antifuses 840 of the multiple switching components 845 may each be coupled with a same digit line 815 (e.g., the antifuses 840 may be connected in parallel).

The digit line decoder 830 and the word line decoder 825 may access the antifuse cell 805 by operating the word line 810 and digit line 815 associated with the antifuse cell 805. For example, to fuse the antifuse cell 805, the word line decoder 825 may activate the switching component 845 to couple the antifuse 840 with the ground voltage source 850, and the digit line decoder 830 may apply a first voltage to the digit line 815. The first voltage may be sufficiently high to cause the oxide material 814 to break down, which may couple (e.g., fuse) the digit line 815 with the channel 812. For example, the first voltage may exceed the gate oxide breakdown voltage of the antifuse 840. Alternatively, the read the antifuse, the word line decoder 825 may activate the switching component 845, and the digit line decoder 830 may apply a second voltage (e.g., a read voltage) to the digit line 815. If the oxide material 814 has been broken down, activating the switching component 845 may couple the digit line 815 with the ground voltage source 850. Alternatively, if the oxide material 814 has not been broken down, the digit line 815 may remain isolated from the ground voltage source 850. A component coupled with the digit line 815 (e.g., a sense component) may sense the current or voltage on the digit line 815 to read the logical state stored by the antifuse cell 805.

FIG. 8C illustrates a top-down view of a system 803 which includes an array of switching components 845. The system 803 may be an example of the system 801, which implements aspects of the system 802 as the switching component 845 and antifuse 840 of an antifuse cell 805. For example, the system 803 may include one or more ground voltage sources 850 extending in the y-direction. Each ground voltage source 850 may be coupled with an antifuse 840 positioned above the ground voltage source 850 via a switching component 845 (e.g., a vertical TFT). The system 803 may include one or more word lines 810 extending in the x-direction, each word line 810 coupled with a row of antifuse cells 805 (e.g., as a gate of each of a row of vertical TFTs).

In some examples, a subset of the vertical TFTs may include an oxide material 814 and conductive contact 855 formed on an upper surface on the vertical TFT. For example, the array of switching components 845 may be arranged according to a pitch 865 in the x-direction (e.g., a distance between adjacent columns). However, to maintain appropriate spacing between adjacent digit lines 815 (e.g., spacing sufficiently large to mitigate shorting or capacitive coupling between digit lines 815) digit lines 815 may be arranged according to a pitch 875 greater than the pitch 865. For example, the pitch 875 may be an integer multiple of the pitch 865, such that each digit line 815 is arranged over a respective conductive contact 855. The integer may be selected based on a spacing that is sufficient for the digit lines 815. Additionally, to maintain appropriate spacing between active word lines 810, conductive contacts 855, or both (e.g., spacing sufficiently large to mitigate shorting or capacitive coupling between adjacent conductive contacts 855 and associated word lines 810), the conductive contacts 855 may be arranged according to a pitch 870 in the y-direction greater than a pitch 872 of the switching components 845 in the y-direction. For example, the pitch 870 may be an integer multiple of the pitch 872, where the integer is selected based on a spacing that is sufficient for the word lines 810 or conductive contacts 855. Accordingly, a minimum size of an antifuse cell 805 may be determined by the pitch 865, the pitch 870, the pitch 872, the pitch 875, or a combination thereof. For example, the antifuse cell 805 illustrated in FIG. 8C may have a dimension in the x-direction (e.g., a length, the pitch 875) corresponding to four times the pitch 865, and may have a dimension in the y-direction (e.g., a height, the pitch 870) corresponding to two times the pitch 872. However, one skilled in the art may recognize such a choice of integers as merely an example, and that other choices are possible. In some examples, the digit lines 815 may be configured as access lines (e.g., bit lines, digit lines) for a memory array. For example, the digit lines 815 may be examples of bit lines for a memory array formed above the system 803. In such cases, the switching component 845 may be configured as a selection component for the memory array.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:

Aspect 1: An apparatus, including: a first layer including a switching component and a first access line extending in a first horizontal direction configured to activate the switching component; and a second layer above the first layer in a vertical direction, the second layer including: an antifuse including a channel extending in the vertical direction and a dielectric material disposed on at least one sidewall of the channel, the channel above a first terminal coupled with the switching component; and a second access line extending in a second horizontal direction perpendicular to the first horizontal direction and coupled with the dielectric material.

Aspect 2: The apparatus of aspect 1, where: the first layer further includes a second switching component coupled with a third access line extending in the first horizontal direction and configured to activate the second switching component; and the second layer further includes a second antifuse coupled with the second access line, the second antifuse including a second channel extending in the vertical direction and the dielectric material disposed on at least one sidewall of the second channel, the second channel above a second terminal coupled with the second switching component, where a semiconductor material forming the channel and the second channel extend from the channel of the antifuse to the second channel of the second antifuse.

Aspect 3: The apparatus of aspect 2, where a first portion of the dielectric material is configured to break down based at least in part on activating the switching component and a second portion of the dielectric material is configured to break down based at least in part on activating the second switching component.

Aspect 4: The apparatus of any of aspects 1 through 3, further including: a third layer between the first layer and the second layer, the third layer including a conductive plate coupling a terminal below the antifuse with the switching component.

Aspect 5: The apparatus of aspect 4, further including: a plurality of second antifuses, each second antifuse of the plurality of second antifuses including a respective channel above a second terminal coupled with the switching component via the conductive plate and a respective dielectric material disposed on at least one respective sidewall of the respective channel.

Aspect 6: The apparatus of aspect 5, where the second access line is coupled with the respective dielectric material of each of a first subset of the plurality of second antifuses and a third access line extending in the second horizontal direction is coupled with the respective dielectric material of each of a second subset of the plurality of second antifuses.

Aspect 7: The apparatus of any of aspects 4 through 6, where the third layer further includes a second conductive plate adjacent to the conductive plate, the second conductive plate coupling a terminal of a second antifuse with a second switching component.

Aspect 8: The apparatus of aspect 7, further including: a third antifuse between the antifuse and the second antifuse, the third antifuse isolated from the conductive plate and the second conductive plate.

Aspect 9: The apparatus of any of aspects 1 through 8, where the switching component includes a first terminal coupled with a ground voltage source and a second terminal coupled with the first terminal of the channel.

Aspect 10: The apparatus of any of aspects 1 through 9, further including: a first decoder coupled with the first access line and configured to apply a first voltage to the first access line to activate the switching component; and a second decoder coupled with the second access line and configured to apply a second voltage to the second access line.

Aspect 11: The apparatus of aspect 10, where the dielectric material is configured to break down based at least in part on activating the switching component and applying the second voltage to the second access line.

Aspect 12: The apparatus of any of aspects 1 through 11, where the switching component includes a complimentary metal-oxide semiconductor (CMOS) transistor within a substrate.

An apparatus is described. The following provides an overview of aspects of the apparatus as described herein:

Aspect 13: An apparatus, including: an antifuse including a channel extending in a vertical direction and a dielectric material disposed on at least one sidewall of the channel; a digit line of a plurality of digit lines extending in a first horizontal direction, the digit line coupled with a terminal below the antifuse; and a word line of a plurality of word lines extending in a second horizontal direction perpendicular to the first horizontal direction and in contact with the dielectric material of the antifuse.

Aspect 14: The apparatus of aspect 13, further including: a digit line decoder

coupled with the plurality of digit lines and configured to select the digit line as part of an access operation for the antifuse; and a word line decoder coupled with the plurality of word lines and configured to select the word line as part of the access operation.

Aspect 15: The apparatus of aspect 14, where as part of a programming operation for the antifuse, the digit line decoder is configured to apply a first voltage of a first polarity to the digit line and the word line decoder is configured to apply a second voltage of a second polarity to the word line.

Aspect 16: The apparatus of aspect 15, where as part of the programming operation, the digit line decoder configures one or more unselected digit lines of the plurality of digit lines in a floating state, and the word line decoder configures one or more unselected word lines of the plurality of word lines in a floating state.

Aspect 17: The apparatus of any of aspects 15 through 16, where a magnitude of the first voltage is equal to a magnitude of the second voltage.

An apparatus is described. The following provides an overview of aspects of the apparatus as described herein:

Aspect 18: An apparatus, including: a first access line extending in a first horizontal direction; a vertical transistor above a first terminal coupled with and above the first access line in a vertical direction, a channel region above the first terminal, and a second terminal above the channel region; a second access line extending in a second horizontal direction perpendicular to the first horizontal direction and coupled with the channel region of the vertical transistor; a dielectric material above the second terminal of the vertical transistor; and a conductive contact coupled with the dielectric material.

Aspect 19: The apparatus of aspect 18, further including: a third access line above the conductive contact and extending in the first horizontal direction, where the third access line is configured as a bit line for an array of memory cells above the vertical transistor.

Aspect 20: The apparatus of aspect 19, where the dielectric material is configured to break down based at least in part on activating the vertical transistor using the second access line, applying a first voltage to the first access line, and applying a second voltage to the third access line.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first layer comprising a switching component and a first access line extending in a first horizontal direction configured to activate the switching component; and
a second layer above the first layer in a vertical direction, the second layer comprising:
an antifuse comprising a channel extending in the vertical direction and a dielectric material disposed on at least one sidewall of the channel, the channel above a first terminal coupled with the switching component; and
a second access line extending in a second horizontal direction perpendicular to the first horizontal direction and coupled with the dielectric material.

2. The apparatus of claim 1, wherein:
the first layer further comprises a second switching component coupled with a third access line extending in the first horizontal direction and configured to activate the second switching component; and
the second layer further comprises a second antifuse coupled with the second access line, the second antifuse comprising a second channel extending in the vertical direction and the dielectric material disposed on at least one sidewall of the second channel, the second channel above a second terminal coupled with the second switching component, wherein a semiconductor material forming the channel and the second channel extend from the channel of the antifuse to the second channel of the second antifuse.

3. The apparatus of claim 2, wherein a first portion of the dielectric material is configured to break down based at least in part on activating the switching component and a second portion of the dielectric material is configured to break down based at least in part on activating the second switching component.

4. The apparatus of claim 1, further comprising:
a third layer between the first layer and the second layer, the third layer comprising a conductive plate coupling a terminal below the antifuse with the switching component.

5. The apparatus of claim 4, further comprising:
a plurality of second antifuses, each second antifuse of the plurality of second antifuses comprising a respective channel above a second terminal coupled with the switching component via the conductive plate and a respective dielectric material disposed on at least one respective sidewall of the respective channel.

6. The apparatus of claim 5, wherein the second access line is coupled with the respective dielectric material of each of a first subset of the plurality of second antifuses and a third access line extending in the second horizontal direction is coupled with the respective dielectric material of each of a second subset of the plurality of second antifuses.

7. The apparatus of claim 4, wherein the third layer further comprises a second conductive plate adjacent to the conductive plate, the second conductive plate coupling a terminal of a second antifuse with a second switching component.

8. The apparatus of claim 7, further comprising:
a third antifuse between the antifuse and the second antifuse, the third antifuse isolated from the conductive plate and the second conductive plate.

9. The apparatus of claim 1, wherein the switching component comprises a first terminal coupled with a ground voltage source and a second terminal coupled with the first terminal of the channel.

10. The apparatus of claim 1, further comprising:
a first decoder coupled with the first access line and configured to apply a first voltage to the first access line to activate the switching component; and
a second decoder coupled with the second access line and configured to apply a second voltage to the second access line.

11. The apparatus of claim 10, wherein the dielectric material is configured to break down based at least in part on activating the switching component and applying the second voltage to the second access line.

12. The apparatus of claim 1, wherein the switching component comprises a complimentary metal-oxide semiconductor (CMOS) transistor within a substrate.

13. An apparatus, comprising:
an antifuse comprising a channel extending in a vertical direction and a dielectric material disposed on at least one sidewall of the channel;
a digit line of a plurality of digit lines extending in a first horizontal direction, the digit line coupled with a terminal below the antifuse; and
a word line of a plurality of word lines extending in a second horizontal direction perpendicular to the first horizontal direction and in contact with the dielectric material of the antifuse.

14. The apparatus of claim 13, further comprising:
a digit line decoder coupled with the plurality of digit lines and configured to select the digit line as part of an access operation for the antifuse; and
a word line decoder coupled with the plurality of word lines and configured to select the word line as part of the access operation.

15. The apparatus of claim 14, wherein as part of a programming operation for the antifuse, the digit line decoder is configured to apply a first voltage of a first polarity to the digit line and the word line decoder is configured to apply a second voltage of a second polarity to the word line.

16. The apparatus of claim 15, wherein as part of the programming operation, the digit line decoder configures one or more unselected digit lines of the plurality of digit lines in a floating state, and the word line decoder configures one or more unselected word lines of the plurality of word lines in a floating state.

17. The apparatus of claim 15, wherein a magnitude of the first voltage is equal to a magnitude of the second voltage.

18. An apparatus, comprising:
a first access line extending in a first horizontal direction;
a vertical transistor above a first terminal coupled with and above the first access line in a vertical direction, a channel region above the first terminal, and a second terminal above the channel region;
a second access line extending in a second horizontal direction perpendicular to the first horizontal direction and coupled with the channel region of the vertical transistor;
a dielectric material above the second terminal of the vertical transistor; and
a conductive contact coupled with the dielectric material.

19. The apparatus of claim 18, further comprising:
a third access line above the conductive contact and extending in the first horizontal direction, wherein the third access line is configured as a bit line for an array of memory cells above the vertical transistor.

20. The apparatus of claim 19, wherein the dielectric material is configured to break down based at least in part on activating the vertical transistor using the second access line, applying a first voltage to the first access line, and applying a second voltage to the third access line.
